(19) United States
(12) Patent Application Publication
(10) Pub. No.: US 2026/0291482 A1
(43) Pub. Date: Sep. 24, 2026

(54) SCALABLE RADIO FREQUENCY SWITCH MATRIX FOR MULTIPORT SIGNAL ROUTING

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/085,923

(22) Filed: Mar. 20, 2025

(51) Int. Cl. H03K 17/00

(52) U.S. Cl. CPC H03K 17/002

(57) ABSTRACT

The technology described herein is directed towards a (e.g., 4×4) mechanical micro-actuator-based RF switch matrix with connection (bridge) switches that controllably connect (e.g., 2×2) unit cell switch submatrices, to facilitate signal routing between any two available RF ports. In one implementation, the switch matrix device provides high isolation between RF transmission paths, including using a crossover and the combination of single and dual-membrane actuators in each unit cell switch submatrix, as well as single and dual-membrane actuators for the connector switches that couple the unit cells together. The switch matrix achieves effective isolation between RF lines, enabling non-blocking, dynamic routing of signals across any available input and output ports. In one implementation, inline ohmic membrane switches are designed for the switch matrix device structure.

### RELATED APPLICATIONS

The subject patent application is related to U.S. patent application No. ______, filed ______, and entitled “BROADBAND RADIO FREQUENCY MICRO-ACTUATOR SWITCH WITH HIGH ISOLATION” (docket no. 141545.01/DELLP1476US), and U.S. patent application No. _________, filed ________, and entitled “SWITCH MATRIX WITH HIGH RADIO FREQUENCY ISOLATION UTILIZING DUAL MECHANICAL MICROMEMBRANE ACTUATORS” (docket no. 141546.01/DELLP1474US), the entireties of which patent applications are hereby incorporated by reference herein.

### BACKGROUND

Radio frequency (RF) switches control the routing of RF signals in communication systems, and are used for tasks like antenna selection and signal path switching. Common types of RF switches include PIN diodes, FET (field effect transistor)/GaN (Gallium Nitride) switches, and MEMS (micro-electromechanical systems) switches, each with unique characteristics in terms of speed, power consumption, and performance.

RF switches are used in devices such as mobile phones, base stations, and phased array antennas for tasks like signal routing, antenna switching, and phase shifting. Important factors for RF switches include insertion loss (signal loss through the switch), isolation (preventing signal leakage between paths), and switching speed (how quickly the switch changes states). Existing RF switches often suffer from at least one of high insertion loss, poor isolation, and/or complex fabrication processes, limiting their applicability in space-constrained high-performance scenarios.

### BRIEF DESCRIPTION OF THE DRAWINGS

The technology described herein is illustrated by way of example and not limited to the accompanying figures in which like reference numerals indicate similar elements and in which:

FIG. 1 is a block diagram representation of an example switch matrix highlighting connector switches between connectable 2×2 unit cells (sub-matrixes) to provide a scalable (e.g., 4×4) switch matrix, in accordance with various example embodiments and implementations of the subject disclosure.

FIGS. 2A and 2B are side views of an example micromembrane actuator showing the general operating principle (open, FIG. 2A, and closed, FIG. 2B) via a cantilever-based connector, in accordance with various example embodiments and implementations of the subject disclosure.

FIG. 3 is a top view representation of an example layout of a 2×2 unit cell switch matrix highlighting various components therein, in accordance with various example embodiments and implementations of the subject disclosure.

FIG. 4 is a top view representation of the example switch matrix of FIG. 1 highlighting one possible path (RF port 1 to RF port 8) selected by actuating selected membrane actuator switches, in accordance with various example embodiments and implementations of the subject disclosure.

FIG. 5 is a top view representation of the example switch matrix of FIG. 1 highlighting another possible path (RF port 1 to RF port 5) selected by actuating selected membrane actuator switches, in accordance with various example embodiments and implementations of the subject disclosure.

FIG. 6 is a top view representation of the example switch matrix of FIG. 1 highlighting yet another possible path (RF port 1 to RF port 7) selected by actuating selected membrane actuator switches, in accordance with various example embodiments and implementations of the subject disclosure.

FIG. 7 is a top view representation of the example switch matrix of FIG. 1 highlighting an alternative path (relative to FIG. 6) from RF port 1 to RF port 7 selected by actuating selected membrane actuator switches, in accordance with various example embodiments and implementations of the subject disclosure.

FIG. 8 is a top view representation of an example layout of the switch matrix of FIG. 1, further including bias pads and RC (resistance (R) and capacitance (C)) lines, in accordance with various example embodiments and implementations of the subject disclosure.

FIGS. 9A, 9B, 10A and 10B are graphical representations of a simulated device's response showing return loss performance for the four paths corresponding to the paths in FIG. 4, FIG. 5, FIG. 6 and FIG. 7, respectively, in accordance with various example embodiments and implementations of the subject disclosure.

FIGS. 11A, 11B, 12A and 12B are graphical representations of a simulated device's response showing insertion loss performance for the four paths corresponding to the paths in FIG. 4 FIG. 5, FIG. 6 and FIG. 7, respectively, in accordance with various example embodiments and implementations of the subject disclosure.

FIG. 13 is a graphical representation of a simulated device's response showing isolation between ports, in accordance with various example embodiments and implementations of the subject disclosure.

FIGS. 14A and 14B are representations of example customized inline switches suitable for implementing a switch matrix, in accordance with various example embodiments and implementations of the subject disclosure.

FIG. 15A is a representation of an inline switch device for use in mechanical simulations, in accordance with various example embodiments and implementations of the subject disclosure.

FIG. 15B is a graphical representation of membrane displacement relative to applied voltage, in accordance with various example embodiments and implementations of the subject disclosure.

FIG. 16 is a graphical representation of a simulated inline switch device performance showing isolation, in accordance with various example embodiments and implementations of the subject disclosure.

FIG. 17 is a graphical representation of a simulated inline switch device performance showing insertion loss, in accordance with various example embodiments and implementations of the subject disclosure.

FIG. 18 is a graphical representation of a simulated inline switch device performance showing return loss (when actuated into an ON state), in accordance with various example embodiments and implementations of the subject disclosure.

FIGS. 19A and 19B are representations of example usage scenarios for the switch matrix, including with low noise block converters (LNBs, FIG. 19A) and block upconverters (BUCs, FIG. 19B), in accordance with various example embodiments and implementations of the subject disclosure.

FIG. 20 is a flow diagram showing example operations related to electrically coupling one or more selectable RF ports to another RF port based on controlling states of mechanical micro-actuator-based switches, in accordance with various aspects and implementations of the subject disclosure.

### DETAILED DESCRIPTION

Various implementations and embodiments of the technology described herein are generally directed towards radio frequency (RF) switch matrix configurations that are scalable based on connecting 2×2 port switch matrix unit-cell (submatrices). The 2×2 unit-cell submatrices can be coupled together to configure an m×n port matrix by incorporating connector switches at specific RF path locations.

In one implementation, a nonlimiting example of a compact 4×4 port switch matrix (e.g., 3.2×6.4 mm) is described and evaluated herein, demonstrating relatively highly suitable RF performance from DC to 20 GHz. This scaled-up 4×4 port switch matrix uses six switch submatrix unit cell (2×2) blocks, and six connector switches between the unit cells blocks, including single-membrane and dual-membrane bridge switches, resulting in a robust switching network with high isolation. In the event of a switch failure, the system can reroute signals within microseconds, ensuring high reliability. The (optional) use of dual-membrane switches enhances isolation between switching states. The result is a switch matrix having up to m×n ports that are suitable for applications requiring rapid, reliable multipath routing, such as including, but not limited to, test and measurement setups, telecommunications, and multifilter radio systems.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

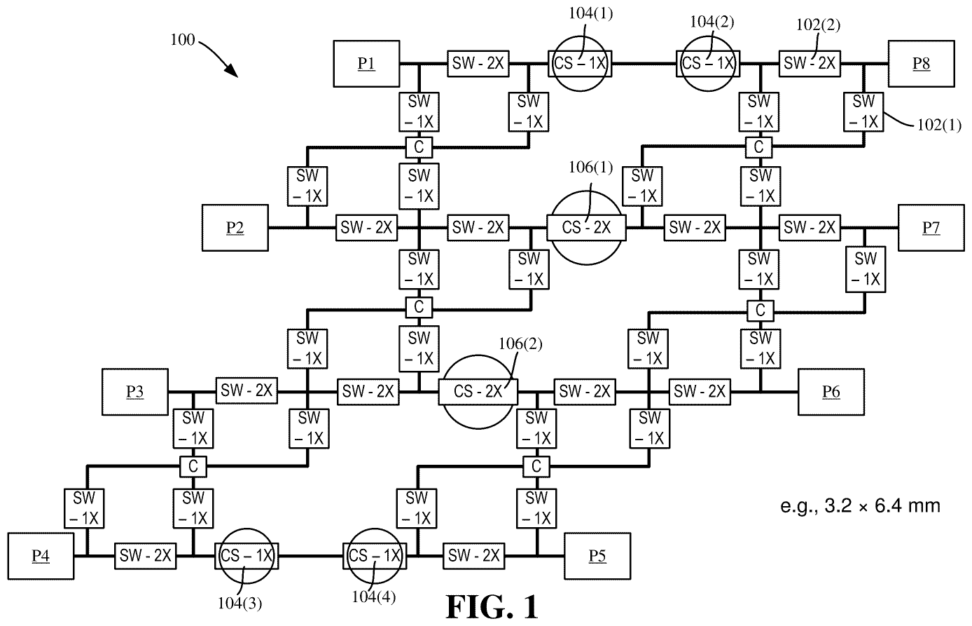

FIG. 1 is a block diagram showing an example 4×4 scalable switch matrix 100 configured from six 2×2 switch submatrices that each include four single ohmic membrane switches and two dual ohmic membrane switches. For purposes of explanation, one of the submatrix single membrane switches (the submatrix single membrane switches are each identified as SW-1X) is labeled 102(1), and one of the submatrix dual membrane switches is labeled 102(2) (the submatrix dual membrane switches are each identified as SW-2X); the other switches are not individually labeled. The switch matrix 100 includes are eight RF ports (P1-P8), and signals can be routed from any available port to any other available port via the transmission (dark black) lines.

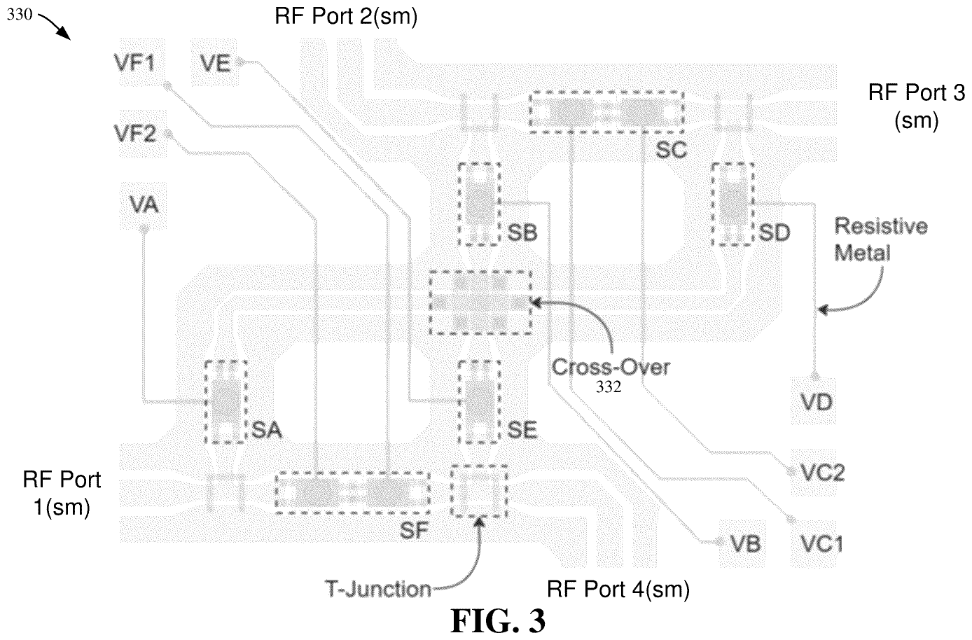

Six connector switches (highlighted by circles in FIG. 1) couple the 2×2 switch submatrices together. In the example implementation depicted, there are four single membrane connected switches 104(1)-104(4); (the single membrane connector switches are each identified as CS-1X). There are two dual membrane connector switches 106(1) and 106(2); (the dual membrane connector switches are each identified as CS-2X). A single membrane switch instead of a dual membrane switch can suffice; however isolation is improved by the use of dual membrane switches. Also note that the blocks labeled “C” represent crossovers, as described with reference to FIG. 3 (there are six crossovers, corresponding to one for each of the six submatrices. In any event, the switch matrix device 100 is relatively compact, and the one depicted in FIG. 1 is on the order of 3.2×6.4 millimeters (mm).

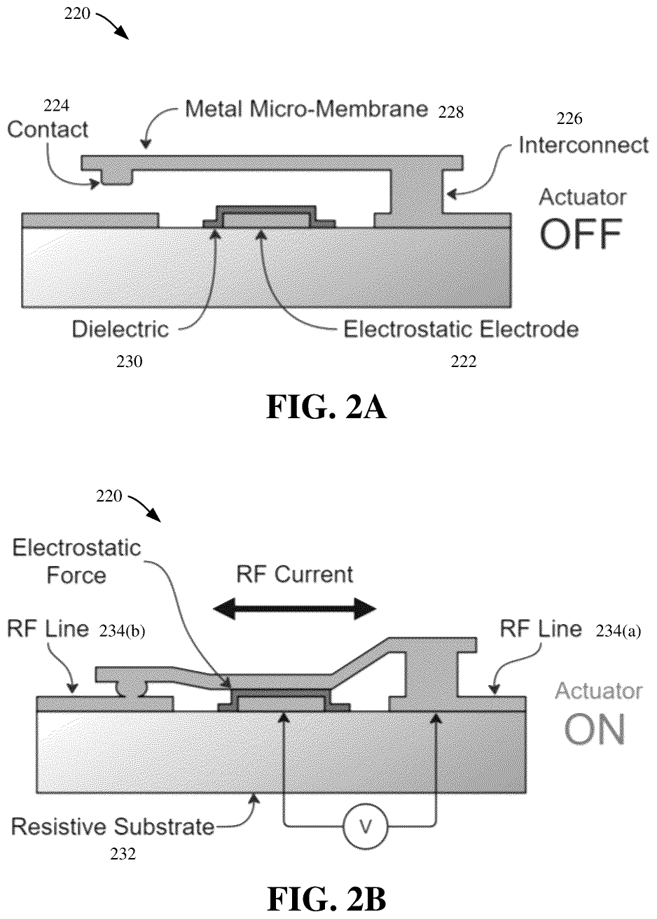

Turning to micromembrane switches in general, FIG. 2A shows an example cantilever type micromembrane actuator 220 in an actuator OFF State, and FIG. 2B shows the example cantilever type micromembrane actuator 220 in an actuator ON state. When no voltage (or too low of a voltage to actuate) is applied to the electrostatic electrode 222 as in FIG. 2A, the micromembrane's contact 224 remains in a lifted due to the structural configuration of the metal micromembrane 228. In this OFF state, RF current (e.g., obtained an interconnect 226) cannot flow across the RF line, effectively isolating the circuit.

FIG. 2B shows electrostatic actuation, in which applying a voltage V difference to the electrode (relative to ground) creates an electrostatic force that pulls the micromembrane 228 down towards the resistive substrate 232. This electrostatic force overcomes the membrane's structural tension, bringing its contact 224 into contact with the RF line 234(b) at its non-anchored end. In this actuator ON state, the electrical coupling between the micromembrane and RF line is established, allowing RF current to pass through. The RF signal can then flow across the circuit, enabling connectivity between the RF lines 234(a) and 234(b). Note that FIG. 2 shows a dielectric 230 that electrically insulates the electrostatic electrode 222 from the RF lines 234(a) and 234(b).

In general, micromembrane actuators enable relatively highly precise, relatively low loss switching in RF systems, offering a reliable alternative to traditional semiconductor and mechanical switches. Their ability to toggle at high-speed with minimal loss, linearity, and high-power handling makes them suitable for reconfigurable antennas, tunable filters, and multi-band communication systems. Note that other, common types of switch configurations include electrostatic, piezoelectric, and thermal actuation switches; each type has certain advantages in terms of speed, power consumption, and mechanical stability. Electrostatic actuators are used due to their low power consumption and rapid actuation.

Further note that while micromembrane actuators were evaluated in the past decade due to their ON-state performance, with micro-scale cantilevers having curvature after manufacturing, in prior micromembrane actuators the isolation performance suffers. Indeed, conventional switch designs, such as microelectromechanical systems (MEMS) switches, face limitations in isolation performance, especially when subjected to high-frequency applications. Moreover, standard MEMS based cantilever solutions also suffer from residual stresses from manufacturing, leading to poor isolation performance. Such designs typically have performance pitfalls from leakage and insufficient isolation, reducing overall system effectiveness. While stacked designs can improve isolation, they often increase complexity and size, which are complex to manufacture and have poor reliability issues.

FIG. 3 shows an example 2×2 mechanical micro-actuator-based RF unit cell switch submatrix (device) 330 that facilitates (e.g., non-blocking) signal routing between any two available RF ports, RF Port 1(sm)-RF Port 4(sm), (where “sm” represents submatrix to avoid any confusion with the RF ports P1-P8 of FIG. 1). The example device includes six switches (SA, SB, SC, SD, SE, SF); four of the switches (SA, SB, SD, SE) are single-membrane actuators and two of the switches (SC, SF) are dual-membrane actuators as described herein. A crossover 332 designed with a tuned permittivity patch provides isolation between intersecting RF lines, allowing simultaneous signal transmission without interference.

The switches are actuated or de-actuated based on whether an actuation voltage is present at contact pads VA, VB, VD, VE for the single-membrane actuators SA, SB, SD, SE, respectively, and VC1, VC2, VF1 and VF2 for the dual-membrane actuators SC and SF (two contact pads each). Note that there can be some resistance (resistive metal) between the contact pads and the switches (their electrostatic electrode or electrodes as described herein) so that the electrostatic energy is appropriate for actuation. T-junctions couple each of the RF ports to corresponding subsets of the switches.

The dual-membrane micro-actuator-based switch can enhance isolation by connecting two micro-cantilevers back-to-back. This back-to-back configuration significantly increases isolation performance by increasing the overall vertical distance between RF lines and contact points which generally gets less due to residual stresses after releasing the cantilever beams. This micro-actuator-based switch configuration also lowers the actuation voltage and lower gap is required to generate sufficient pull-in force between membrane and electrode, making it well-suited for applications demanding high signal integrity. Through-substrate interconnects provide DC power for the electrostatic actuation, allowing precise control over switch states. The design also offers a compact form factor, ideal for integration in RF systems where space and performance are critical.

The technology provides a mechanical micro-actuator-based switch submatrix designed for high isolation between RF transmission paths. Utilizing a crossover with a tuned permittivity patch and a mix of single and dual-membrane actuators, the mechanical micro-actuator-based switch matrix device achieves effective isolation between RF lines, and can enable non-blocking, dynamic routing of signals across any available input and output ports. One implementation of the submatrix includes six switches, four of which use single-membrane actuators, while two feature dual-membrane actuators. Through-substrate interconnects help to minimize RF and DC interference, providing a scalable solution to address challenges in insertion loss consistency and isolation performance in RF switch matrices.

When interconnected as in FIG. 1 to obtain the 4×4 RF switch matrix 100, the 2×2 micro-actuator-based RF submatrices act as unit cells that scale up to larger (m×n) configurations. In the implementation of FIG. 1, the depicted design utilizes six 2×2 unit-cell blocks, each comprising a matrix of micro-actuator switches, coupled together by six additional connector switches. These connectors include single-membrane (104(1)-104(4)) and dual-membrane (106(1) and 106(2)) bridge switches, where dual membranes provide enhanced isolation between switching states.

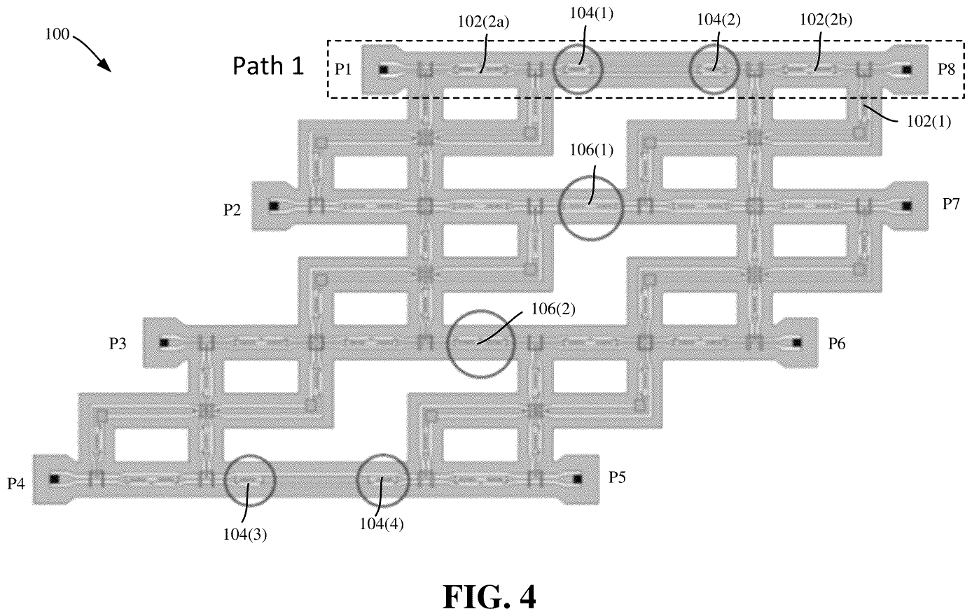

Turning to some of the many possible paths, FIG. 4 shows a first path, Path 1, from port P1 to port P8 (the dashed block shows the path). As can be seen, two switches 102(2a) and 102(2b) of interconnected unit cells are actuated, interconnected by connector switches 104(1) and 104(2). Other switches are de-actuated (unless used in another path, e.g., port 2 could be independently coupled to port 6 at the same time).

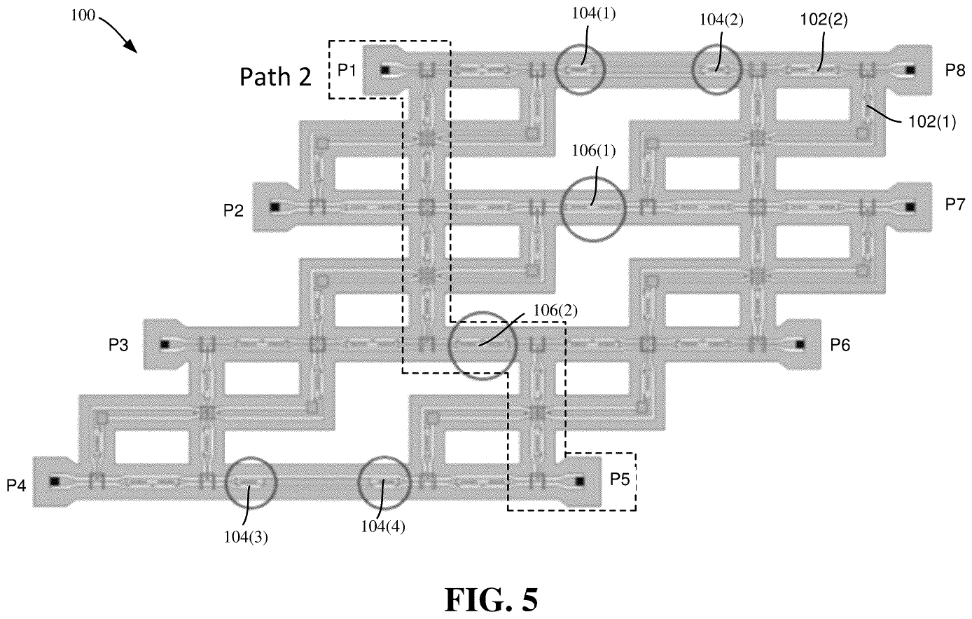

FIG. 5 shows a second path of the many possible paths, Path 2, from port P1 to port P5. As can be seen, a dual membrane connector switch 106(2) is actuated to provide the path (the individual unit cell switches in Path 2 are not labeled, but as is understood, those of them in Path 2 are actuated).

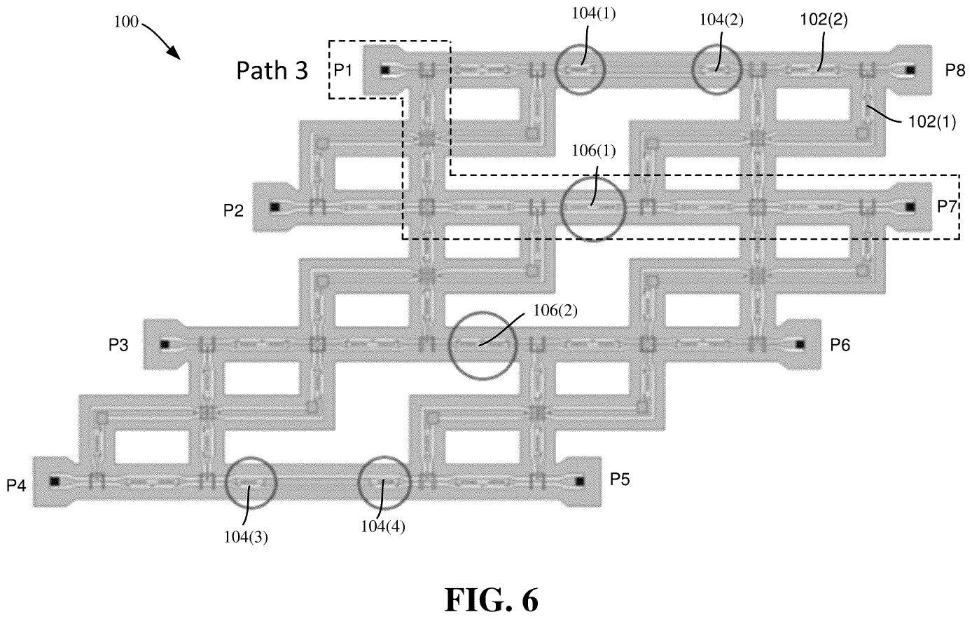

FIG. 6 shows a third path, Path 3, from port P1 to port P7. As can be seen, a dual membrane connector switch 106(1) is actuated to provide the path (the individual unit cell switches in Path 3 are not labeled).

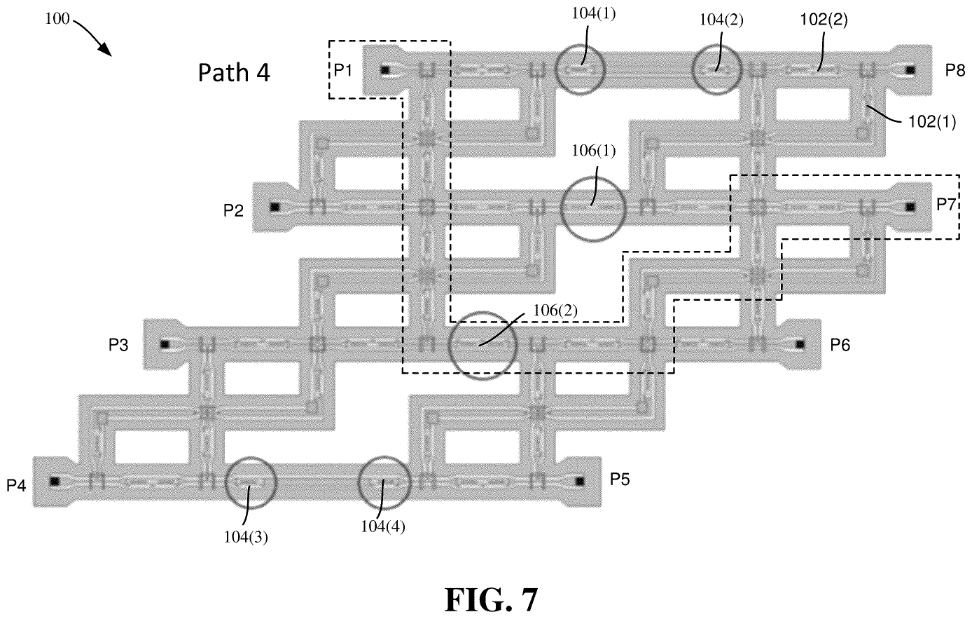

FIG. 7 shows a third path, Path 4, again from port P1 to port P7 but over a different route relative to FIG. 6. As can be seen, a dual membrane connector switch 106(2) is actuated to provide the path (the individual unit cell switches in the Path 4 are not labeled). This alternative path can be taken if one of the switches in Path 3 has failed, for example; note that there are other alternative paths from port P1 to P7.

Along with providing high isolation, the 4×4 RF switch matrix 100 allows alternative routing paths in case of switch failures, enabling rapid signal rerouting within microseconds. Although port P1 was used in the examples, a similar variety of selectable paths are available for the other ports.

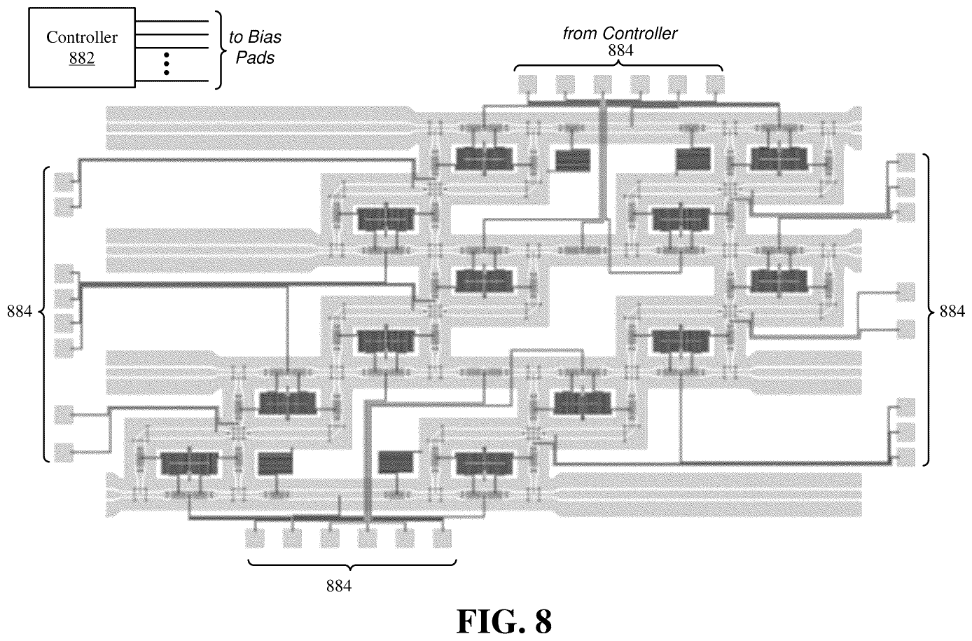

FIG. 8 shows a system 880 that includes a controller 882, and shows the bias pads (collectively 884) for selectively applying voltage to the electrode (e.g., 222 of FIG. 2A) of each switch (or dual electrodes for each dual membrane switch). Note that the voltage can be different per electrode, such as to compensate for any fabrication tolerance differences. Also shown in FIG. 8 are RC (resistance (R) and capacitance (C)) lines.

Note that traditional RF switch matrices face limitations in scalability, cost, and mechanical reliability. Bulky mechanical microwave switches conventionally used in larger setups are very expensive and difficult to integrate into compact systems. Additionally, alternative solutions often suffer from poor isolation and lack of redundancy, making them unsuitable for high-performance applications that want flexible, multiport RF signal routing with rapid failsafe capabilities. The technology described herein facilitates a compact, scalable RF switch matrix that provides high isolation, low insertion loss, and rapid rerouting options for signal integrity and reliability.

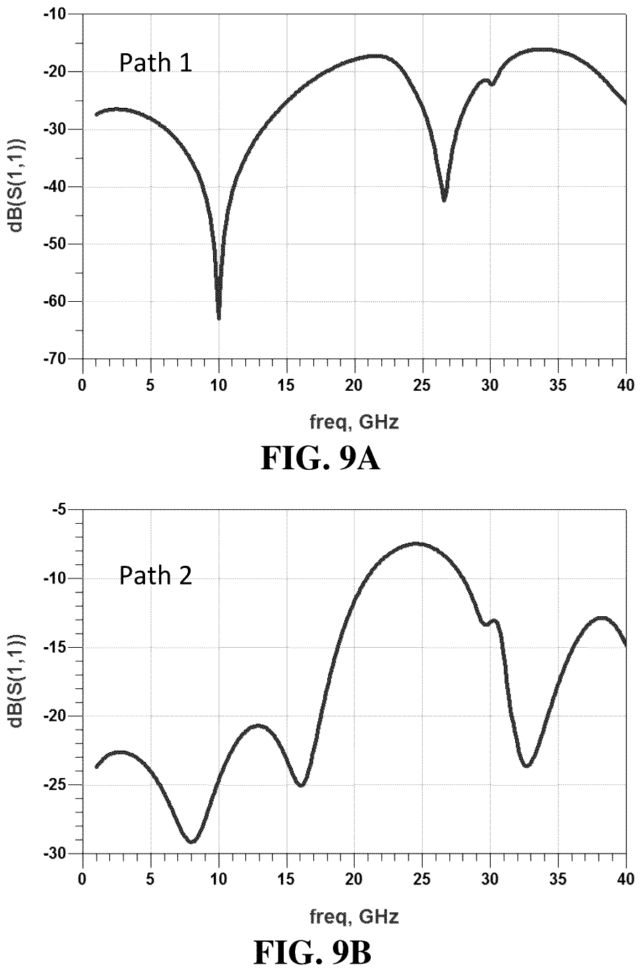

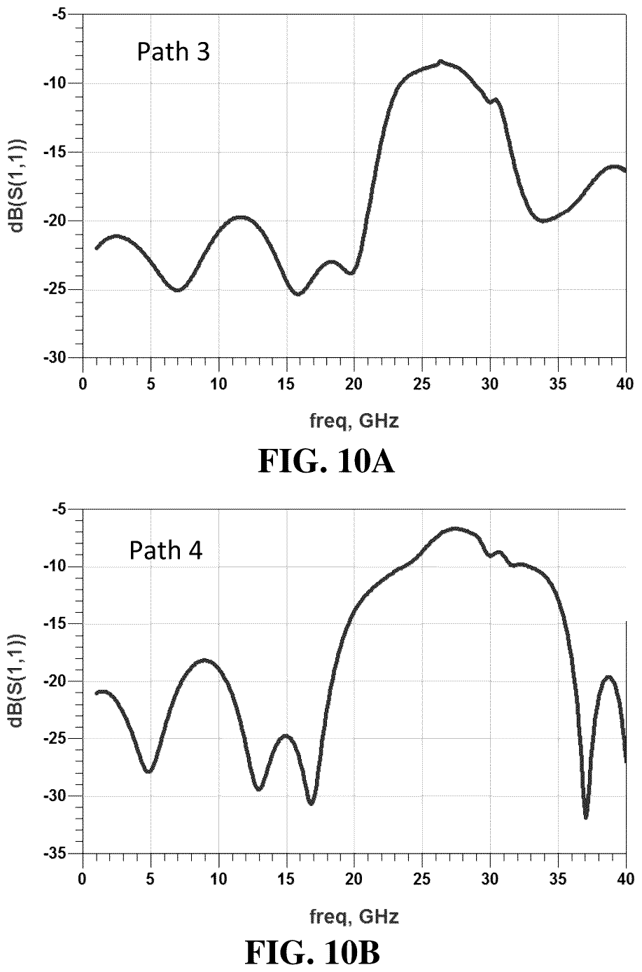

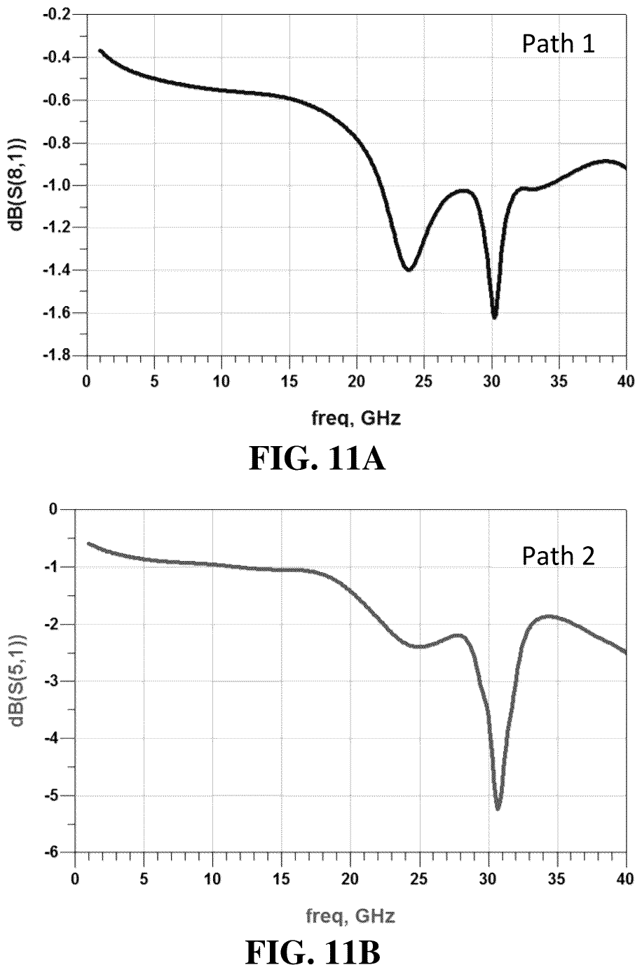

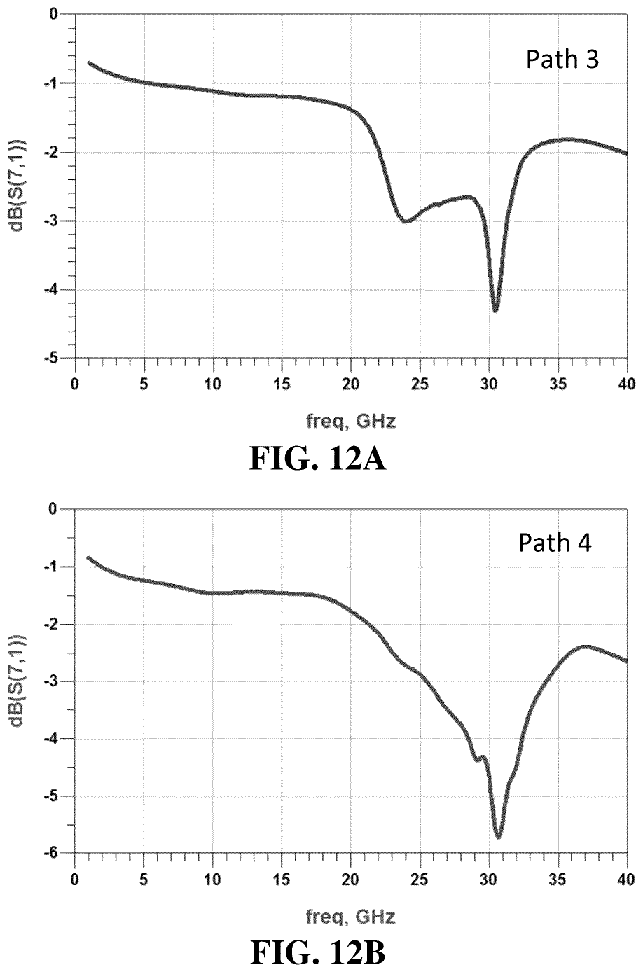

FIGS. 9A, 9B, 10A and 10B are graphical representations of a simulated device response showing return loss performance in dB from 0 -40 GHz for the four paths corresponding to the paths in FIG. 4, FIG. 5, FIG. 6 and FIG. 7, respectively. FIGS. 11A, 11B, 12A and 12B are graphical representations of a simulated device response showing insertion loss performance in dB from 0 -40 GHz for the four paths corresponding to the paths in FIG. 4 FIG. 5, FIG. 6 and FIG. 7, respectively, in accordance with various example embodiments and implementations of the subject disclosure.

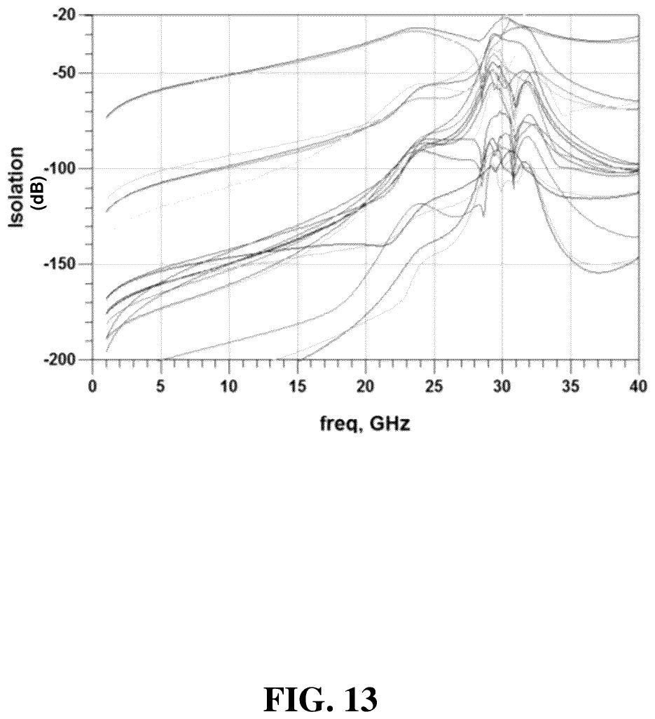

FIG. 13 is a graphical representation of a simulated device response showing isolation (in dB) between ports. The switch device has more than adequate isolation performance between multiple ports. Indeed, the isolation always stays lower than −20 dB over the entire 0-40 GHz band. Note that the −20 dB value corresponds to one percent (1%) of the signal leaking through, and ninety-nine percent (99%) isolated.

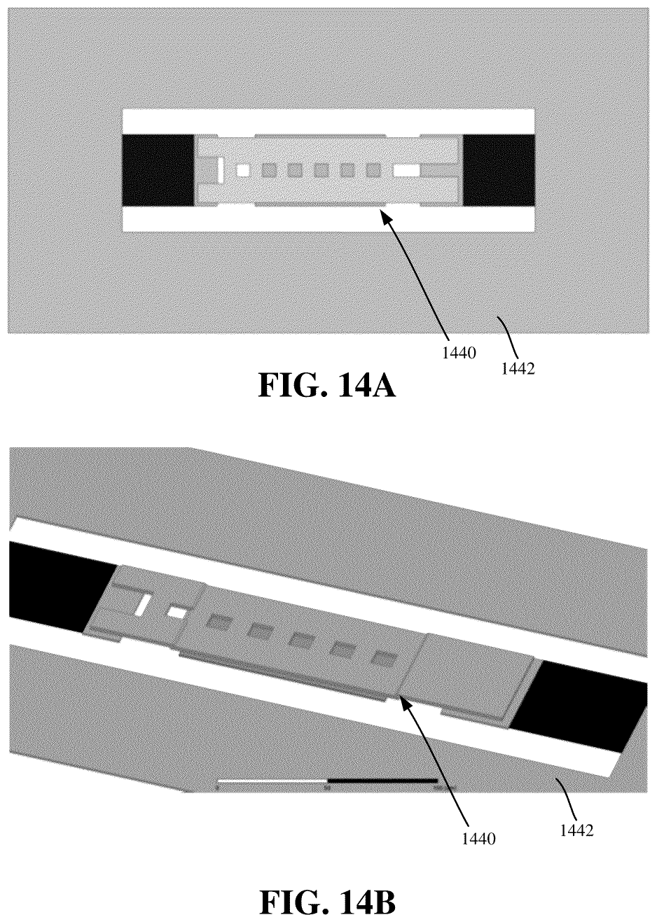

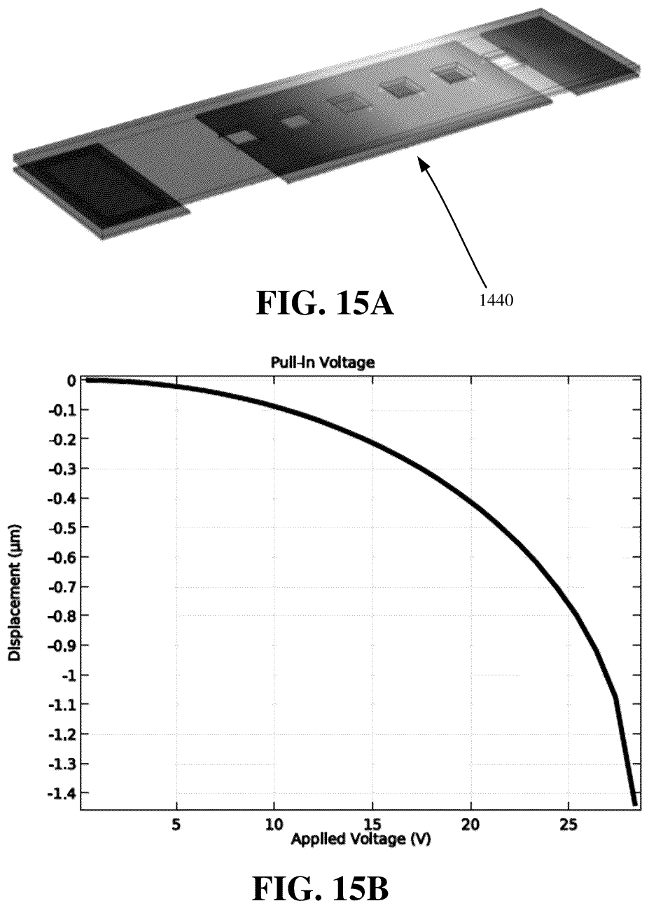

As shown in FIG. 14A, (top view), 14B and 15A (3D view), a custom-designed ohmic membrane switch 1440, (shown in FIGS. 14A and 14B isolated from and surrounded by ground 1442), is implemented to maintain simplicity and reliability, with mechanical finite element modeling employed to optimize electrostatic pull-in force. FIG. 15B shows the cantilever displacement (in mm) based on applied voltage in volts (V). These switches were used in the switch matrix 100 of FIG. 1 designed and optimized in Ansys HFSS. Note that lumped ports (represented in FIG. 1 as black squares for P1-P8) were used in simulations.

The inline switches designed for this specific switch matrix have an electrostatic contact pad under the ohmic membrane. Two contact points create distributed force at the output side of the inline switch. The switch has an operational voltage of 28 V, and the DC can be carried over the RF line by using a bias-Tee at the input of a programmable network analyzer, for example.

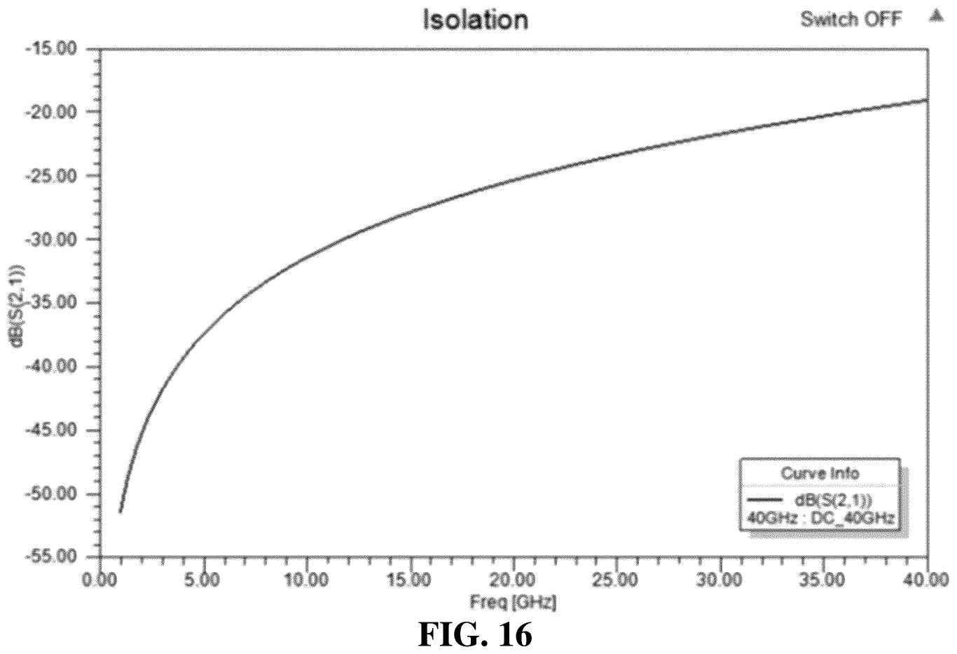

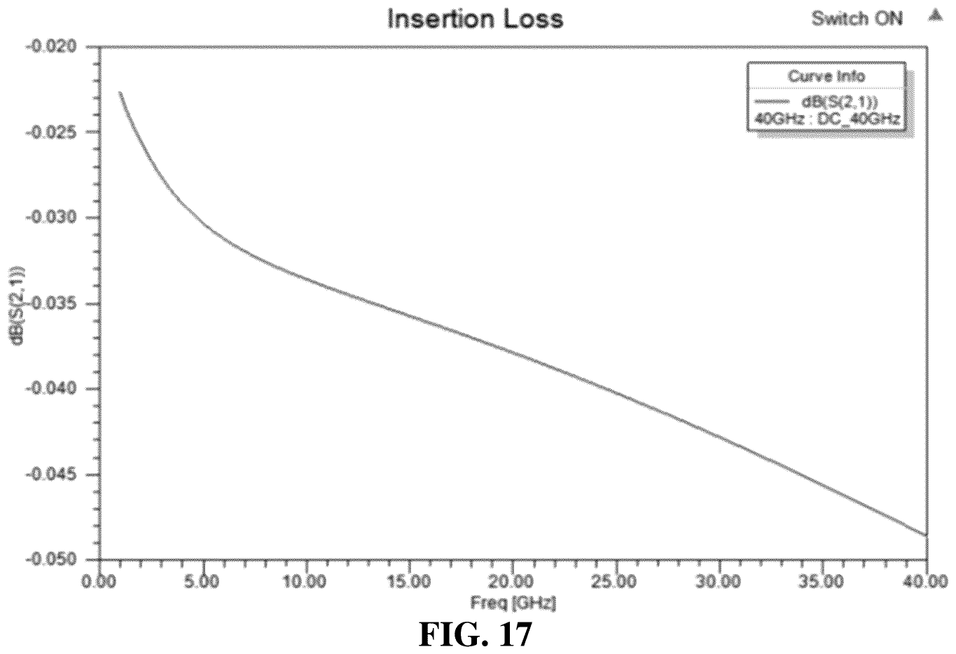

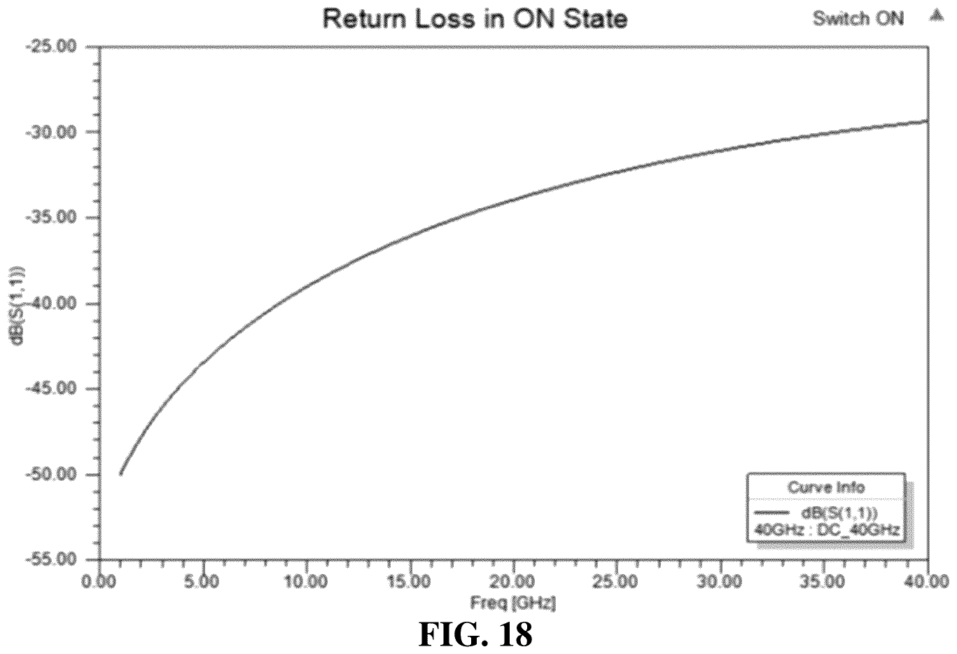

FIG. 16-18 show the simulated inline switch performance, in dB, for frequencies ranging from near zero to 40 GHz. In particular, FIG. 16 shows isolation performance, FIG. 17 shows insertion loss performance, and FIG. 18 shows return loss performance while the switch is in its ON (actuated) state.

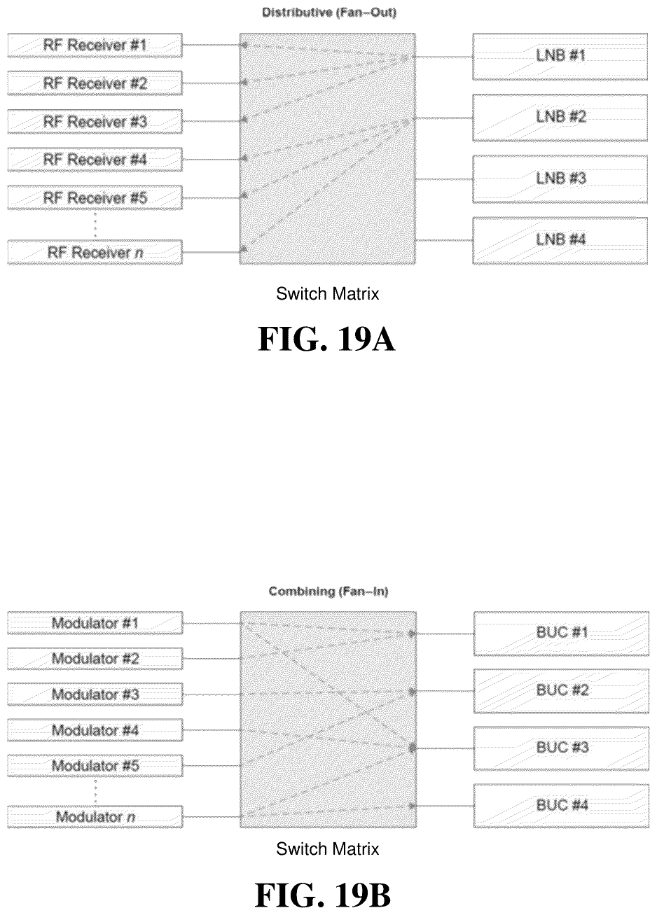

FIGS. 19A and 19B are representations of example usage scenarios for the switch matrix. FIG. 19A shows a distributive (fan-out) scenario with low noise block converters (LNBs) selectively routed to receivers. FIG. 19B shows a distributive (fan-in) scenario with modulators selectively routed to block upconverters (BUCs).

One or more implementations can be embodied in a device, including a radio frequency (RF) switch matrix. The RF switch matrix can include a radio frequency (RF) switch matrix, including RF ports, respective unit cell switch matrix devices, the respective unit cell switch matrix devices including respective groups of mechanical micro-actuator-based switches coupled to the RF ports, and respective connector switches coupled between the respective unit cell switch matrix devices. Application of first respective voltages selectively controlled by at least one controller can determine a first operational state of the respective unit cell switch matrix devices, including a first subgroup of the respective mechanical micro-actuator-based switches controlled to be in first actuated states, and a second subgroup of the respective mechanical micro-actuator-based switches controlled to be in first de-actuated states. Application of second respective voltages selectively controlled by the at least one controller can determine a second operational state of the respective connector switches including second actuated states and second de-actuated states. The first operational state of the respective unit cell switch matrix devices, in conjunction with the second operational state of the respective connector switches, couples a first RF port of the RF ports to a second RF port of the RF ports.

The first subgroup of the respective mechanical micro-actuator-based switches can include at least four respective mechanical micro-actuator-based switches controlled to be in the first actuated states.

At least one of the at least four respective mechanical micro-actuator-based switches can include a dual-membrane-cantilever switch device.

At least one of the connector switches can include a dual-membrane-cantilever switch device.

The first operational state of the respective unit cell switch matrix devices, in conjunction with the second operational state of the respective connector switches, can couple a third RF port of the RF ports to a fourth RF port of the RF ports.

Application of third respective voltages selectively controlled by the at least one controller can determine a third operational state of the respective unit cell switch matrix devices, including a third subgroup of the respective mechanical micro-actuator-based switches controlled to be in third actuated states, and a fourth subgroup of the respective mechanical micro-actuator-based switches controlled to be in third de-actuated states; application of fourth respective voltages selectively controlled by the at least one controller can determine a fourth operational state of the respective connector switches including fourth actuated states and fourth de-actuated states. The third operational state of the respective unit cell switch matrix devices, in conjunction with the fourth operational state of the respective connector switches, can couple the first RF port to a third RF port of the RF ports.

The third operational state, in conjunction with the fourth operational state, can electrically decouple the first RF port from the second RF port.

The third operational state, in conjunction with the fourth operational state, can electrically couple the second RF port to a fourth RF port of the RF ports.

The RF switch matrix can include six unit cell switch matrix devices. Each unit cell switch matrix device can include six of the respective mechanical micro-actuator-based switches. The respective connector switches can include six other mechanical micro-actuator-based switches, other than the respective mechanical micro-actuator-based switches of the unit cell switch matrix devices.

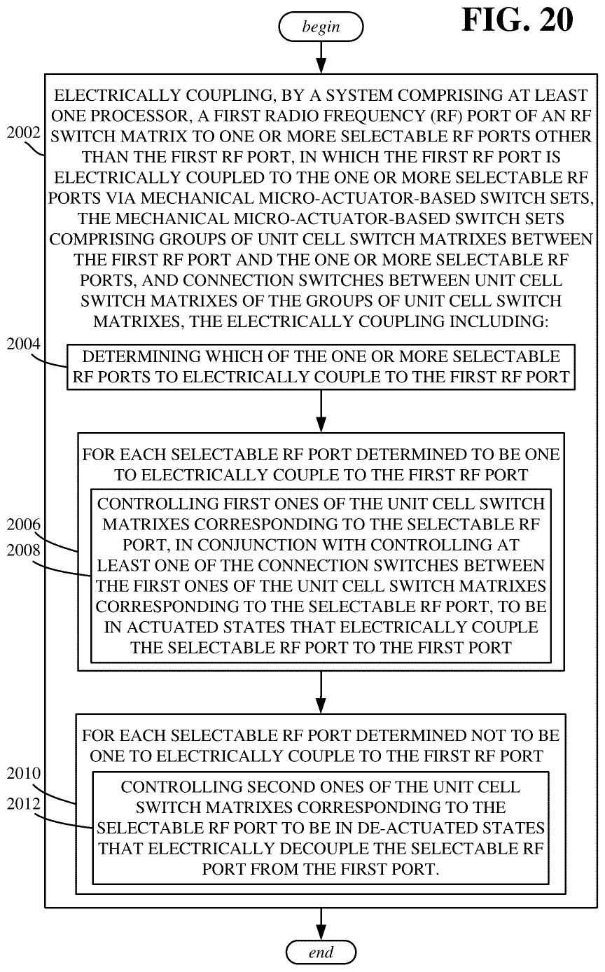

One or more example embodiments, implementations, and/or operations, such as corresponding to example operations of a method, can be represented in FIG. 20. Example operation 2002 represents electrically coupling, by a system comprising at least one processor, a first radio frequency (RF) port of an RF switch matrix to one or more selectable RF ports other than the first RF port, in which the first RF port can be electrically coupled to the one or more selectable RF ports via mechanical micro-actuator-based switch sets, the mechanical micro-actuator-based switch sets comprising groups of unit cell switch matrixes between the first RF port and the one or more selectable RF ports, and connection switches between unit cell switch matrixes of the groups of unit cell switch matrixes. The electrically coupling includes example operations 2004-2012. Example operation 2004 represents determining which of the one or more selectable RF ports to electrically couple to the first RF port. Example operation 2006 represents, for each selectable RF port determined to be one to electrically couple to the first RF port, controlling first ones of the unit cell switch matrixes corresponding to the selectable RF port, in conjunction with controlling at least one of the connection switches between the first ones of the unit cell switch matrixes corresponding to the selectable RF port, to be in actuated states that electrically couple the selectable RF port to the first port (example operation 2008). Example operation 2010 represents, for each selectable RF port determined not to be one to electrically couple to the first RF port, controlling second ones of the unit cell switch matrixes corresponding to the selectable RF port to be in de-actuated states that electrically decouple the selectable RF port from the first port (example operation 2012).

Controlling the mechanical micro-actuator-based switch set corresponding to the selectable RF port to change the mechanical micro-actuator-based switch set to the actuated state can include applying at least one voltage to at least one contact pad coupled to the mechanical micro-actuator-based switch set to set the mechanical micro-actuator-based switch set to the actuated state.

At least one of the mechanical micro-actuator-based switch sets can include a dual-switch device, and applying the at least one voltage to the at least one contact pad can include applying a first voltage to a first contact pad coupled to a first switch of the dual-switch device, and applying a second voltage to a second contact pad coupled to a second switch of the dual-switch device.

The first RF port can be an output port, and further operations can include determining, by the system, a single selectable RF port of the one or more selectable RF ports to be an input port that obtains an input signal; the electrically coupling can couple the single selectable RF port to the first RF port.

The electrically coupling can be a first electrical coupling operation that can couple the first RF port to an eighth RF port of the one or more selectable RF ports via at least one first subset of the mechanical micro-actuator-based switch sets being controlled to be in first actuated states, can decouple the first RF port from remaining RF ports, other than the eighth RF port, of the one or more selectable RF ports via at least one second subset of the mechanical micro-actuator-based switch set controlled to be in a first de-actuated state; further operations can include, in a second electrically coupling operation, electrically coupling, by the system, the first RF port to a seventh RF port via at least one third subset of the mechanical micro-actuator-based switch sets being controlled to be in second actuated states that electrically couple the first RF port to a seventh RF port.

The second electrically coupling operation can electrically couple the first RF port to the seventh RF port via first path through the mechanical micro-actuator-based switch sets; further operations can include in a third electrically coupling operation, electrically coupling, by the system, the first RF port to the seventh RF port via at least one fourth subset of the mechanical micro-actuator-based switch sets being controlled to be in third actuated states that electrically couple the first RF port to the seventh RF port via second path through the mechanical micro-actuator-based switch sets that can be different from the first path.

One or more implementations can be embodied in an RF switch matrix. The RF switch matrix can include RF ports, and respective unit cell switch matrix devices; the respective unit cell switch matrix devices can include respective groups of mechanical micro-actuator-based switches coupled to the RF ports, and respective connector switches coupled between the respective unit cell switch matrix devices. Application of first respective voltages selectively controlled by at least one controller can determine a first operational state of a first RF switch matrix of the respective unit cell switch matrix devices, corresponding to a first subgroup of respective mechanical micro-actuator-based switches controlled to be in first actuated states, and a second subgroup of respective mechanical micro-actuator-based switches controlled to be in first de-actuated states. Application of second respective voltages selectively controlled by the at least one controller can determine a second operational state of a second RF switch matrix of the respective unit cell switch matrix devices, corresponding to a third subgroup of the respective mechanical micro-actuator-based switches controlled to be in second actuated states, and a fourth subgroup of respective mechanical micro-actuator-based switches controlled to be in second de-actuated states. Application of third respective voltages selectively controlled by the at least one controller can determine a third operational state of the respective connector switches, and the third operational state of the respective connector switches, in conjunction with the first operational state and the second operational state, can couple a first input port of the respective sets of RF ports to an eighth RF port of the RF ports.

The RF switch matrix can include a four-by-four RF switch matrix that can include eight RF ports, six respective unit cell switch matrix devices that can include six respective groups of mechanical micro-actuator-based switches coupled to the RF ports, and six respective connector switches coupled between the respective unit cell switch matrix devices.

At least one of: at least one mechanical micro-actuator-based switch of the mechanical micro-actuator-based switches can include a first dual-membrane-cantilever switch device, or at least one connector switch of the respective connector switches can include a second dual-membrane-cantilever switch device.

As can be seen, the technology described herein facilitates a highly efficient, low loss, and compact radio frequency (RF) switch matrix. The switch matrix integrates mechanical micro-actuator-based switch devices, configured as multiple submatrices connected by micro-actuator-based connector switches to facilitate scaling, enabling multistate operation for routing an input signal from any available port to any available free port, such as embodied in an eight-port switch with distinct states for flexible signal routing across multiple ports. The unit-cell design approach enables the creation of larger m×n matrices, demonstrated herein with a 4×4 configuration, allowing for straightforward expansion to larger switch arrays. The scalability achieved by connecting unit cells (submatrix devices) using bridge (connector) switches. By incorporating both single and dual-membrane bridge switches, the design provides flexibility in isolation performance. High isolation is accomplished via the dual-membrane switches, which increase isolation between states; fail-safe routing is accomplished via the matrix structure facilitating quick rerouting in case of a switch failure, ensuring reliability in applications.

Further, the technology results in a compact, cost-effective alternative to bulky mechanical switches. The compact (e.g., 4×4) matrix provides a cost-effective solution for applications traditionally requiring expensive, large mechanical microwave switches.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a radio frequency (RF) switch matrix, comprising:
RF ports;
respective unit cell switch matrix devices, the respective unit cell switch matrix devices comprising respective groups of mechanical micro-actuator-based switches coupled to the RF ports; and
respective connector switches coupled between the respective unit cell switch matrix devices,
wherein application of first respective voltages selectively controlled by at least one controller determines a first operational state of the respective unit cell switch matrix devices, comprising a first subgroup of the respective mechanical micro-actuator-based switches controlled to be in first actuated states, and a second subgroup of the respective mechanical micro-actuator-based switches controlled to be in first de-actuated states, and
wherein application of second respective voltages selectively controlled by the at least one controller determines a second operational state of the respective connector switches comprising second actuated states and second de-actuated states, and
wherein the first operational state of the respective unit cell switch matrix devices, in conjunction with the second operational state of the respective connector switches, couples a first RF port of the RF ports to a second RF port of the RF ports.

2. The device of claim 1, wherein the first subgroup of the respective mechanical micro-actuator-based switches comprises at least four respective mechanical micro-actuator-based switches controlled to be in the first actuated states.

3. The device of claim 2, wherein at least one of the at least four respective mechanical micro-actuator-based switches comprises a dual-membrane-cantilever switch device.

4. The device of claim 1, wherein at least one of the connector switches comprises a dual-membrane-cantilever switch device.

5. The device of claim 1, wherein the first operational state of the respective unit cell switch matrix devices, in conjunction with the second operational state of the respective connector switches, couples a third RF port of the RF ports to a fourth RF port of the RF ports.

6. The device of claim 1, wherein application of third respective voltages selectively controlled by the at least one controller determines a third operational state of the respective unit cell switch matrix devices, comprising a third subgroup of the respective mechanical micro-actuator-based switches controlled to be in third actuated states, and a fourth subgroup of the respective mechanical micro-actuator-based switches controlled to be in third de-actuated states, and wherein application of fourth respective voltages selectively controlled by the at least one controller determines a fourth operational state of the respective connector switches comprising fourth actuated states and fourth de-actuated states, and
wherein the third operational state of the respective unit cell switch matrix devices, in conjunction with the fourth operational state of the respective connector switches, couples the first RF port to a third RF port of the RF ports.

7. The device of claim 6, wherein the third operational state, in conjunction with the fourth operational state, electrically decouples the first RF port from the second RF port.

8. The device of claim 6, wherein the third operational state, in conjunction with the fourth operational state, electrically couples the second RF port to a fourth RF port of the RF ports.

9. The device of claim 1, wherein the RF switch matrix comprises six unit cell switch matrix devices.

10. The device of claim 9, wherein each unit cell switch matrix device comprises six of the respective mechanical micro-actuator-based switches.

11. The device of claim 9, wherein the respective connector switches comprise six other mechanical micro-actuator-based switches, other than the respective mechanical micro-actuator-based switches of the unit cell switch matrix devices.

12. A method, comprising:
electrically coupling, by a system comprising at least one processor, a first radio frequency (RF) port of an RF switch matrix to one or more selectable RF ports other than the first RF port, wherein the first RF port is electrically coupled to the one or more selectable RF ports via mechanical micro-actuator-based switch sets, the mechanical micro-actuator-based switch sets comprising groups of unit cell switch matrixes between the first RF port and the one or more selectable RF ports, and connection switches between unit cell switch matrixes of the groups of unit cell switch matrixes, the electrically coupling comprising:
determining which of the one or more selectable RF ports to electrically couple to the first RF port;
for each selectable RF port determined to be one to electrically couple to the first RF port,
controlling first ones of the unit cell switch matrixes corresponding to the selectable RF port, in conjunction with controlling at least one of the connection switches between the first ones of the unit cell switch matrixes corresponding to the selectable RF port, to be in actuated states that electrically couple the selectable RF port to the first port; and
for each selectable RF port determined not to be one to electrically couple to the first RF port,
controlling second ones of the unit cell switch matrixes corresponding to the selectable RF port to be in de-actuated states that electrically decouple the selectable RF port from the first port.

13. The method of claim 12, wherein the controlling of the mechanical micro-actuator-based switch set corresponding to the selectable RF port to change the mechanical micro-actuator-based switch set to the actuated state comprises applying at least one voltage to at least one contact pad coupled to the mechanical micro-actuator-based switch set to set the mechanical micro-actuator-based switch set switch set to the actuated state.

14. The method of claim 12, wherein at least one of the mechanical micro-actuator-based switch sets comprises a dual-switch device, and wherein the applying of the at least one voltage to the at least one contact pad comprises applying a first voltage to a first contact pad coupled to a first switch of the dual-switch device, and applying a second voltage to a second contact pad coupled to a second switch of the dual-switch device.

15. The method of claim 12, wherein the first RF port is an output port, and further comprising determining, by the system, a single selectable RF port of the one or more selectable RF ports to be an input port that obtains an input signal,
wherein the electrically coupling couples the single selectable RF port to the first RF port.

16. The method of claim 12, wherein the electrically coupling is a first electrical coupling operation that:
couples the first RF port to an eighth RF port of the one or more selectable RF ports via at least one first subset of the mechanical micro-actuator-based switch sets being controlled to be in first actuated states,
decouples the first RF port from remaining RF ports, other than the eighth RF port, of the one or more selectable RF ports via at least one second subset of the mechanical micro-actuator-based switch set controlled to be in a first de-actuated state, and further comprising:
in a second electrically coupling operation, electrically coupling, by the system, the first RF port to a seventh RF port via at least one third subset of the mechanical micro-actuator-based switch sets being controlled to be in second actuated states that electrically couple the first RF port to a seventh RF port.

17. The method of claim 12, wherein the second electrically coupling operation electrically couples the first RF port to the seventh RF port via first path through the mechanical micro-actuator-based switch sets, and further comprising:
in a third electrically coupling operation, electrically coupling, by the system, the first RF port to the seventh RF port via at least one fourth subset of the mechanical micro-actuator-based switch sets being controlled to be in third actuated states that electrically couple the first RF port to the seventh RF port via second path through the mechanical micro-actuator-based switch sets that is different from the first path.

18. A radio frequency (RF) switch matrix, comprising:
RF ports;
respective unit cell switch matrix devices, the respective unit cell switch matrix devices comprising respective groups of mechanical micro-actuator-based switches coupled to the RF ports; and
respective connector switches coupled between the respective unit cell switch matrix devices,
wherein application of first respective voltages selectively controlled by at least one controller determines a first operational state of a first RF switch matrix of the respective unit cell switch matrix devices, corresponding to a first subgroup of respective mechanical micro-actuator-based switches controlled to be in first actuated states, and a second subgroup of respective mechanical micro-actuator-based switches controlled to be in first de-actuated states,
wherein application of second respective voltages selectively controlled by the at least one controller determines a second operational state of a second RF switch matrix of the respective unit cell switch matrix devices, corresponding to a third subgroup of the respective mechanical micro-actuator-based switches controlled to be in second actuated states, and a fourth subgroup of respective mechanical micro-actuator-based switches controlled to be in second de-actuated states,
wherein application of third respective voltages selectively controlled by the at least one controller determines a third operational state of the respective connector switches, and
wherein the third operational state of the respective connector switches, in conjunction with the first operational state and the second operational state, couples a first input port of the respective sets of RF ports to an eighth RF port of the RF ports.

19. The RF switch matrix of claim 18, wherein the RF switch matrix comprises a four-by-four RF switch matrix comprising eight RF ports, six respective unit cell switch matrix devices comprising six respective groups of mechanical micro-actuator-based switches coupled to the RF ports, and six respective connector switches coupled between the respective unit cell switch matrix devices.

20. The RF switch matrix of claim 18, wherein at least one of: at least one mechanical micro-actuator-based switch of the mechanical micro-actuator-based switches comprises a first dual-membrane-cantilever switch device, or wherein at least one connector switch of the respective connector switches comprises a second dual-membrane-cantilever switch device.
